(19) United States
(12) Patent Application Publication
(10) Pub. No.: US 2019/0189908 A1
(43) Pub. Date: Jun. 20, 2019

(54) Heterostructures for Electric Field Controlled Magnetic Tunnel Junctions

(71) Applicant: Inston Inc., Santa Monica, CA (US)

(72) Inventors: Farbod Ebrahimi, Santa Monica, CA (US); Xiang Li, Santa Monica, CA (US)

(73) Assignee: Inston Inc., Santa Monica, CA (US)

(21) Appl. No.: 16/228,347

(22) Filed: Dec. 20, 2018

Related U.S. Application Data
(60) Provisional application No. 62/608,506, filed on Dec. 20, 2017.

(51) Int. Cl. H01L 43/02; H01L 43/10

(52) U.S. Cl. CPC H01L 43/02; H01L 27/222; H01L 43/10

(57) ABSTRACT

In various embodiments, magnetic heterostructures and magnetic layers can be implemented and configured to provide electric field controlled magnetic tunnel junctions. Such magnetic heterostructures and magnetic layers can incorporate a variety of different materials and layers for various effects. In many embodiments, the magnetic heterostructures incorporate hybrid seed layers. Such layers can be incorporated for various reasons including but not limited to producing an enhanced voltage controlled magnetic anisotropy (“VCMA”) effect. The VCMA effect can be explained in terms of the electric-field-induced change of occupancy of atomic orbitals at the interface, which, in conjunction with spin-orbit interaction, results in a change of anisotropy. In some embodiments, the magnetic heterostructures and layers incorporate free layer insertions. In a number of embodiments, the magnetic heterostructures incorporate a material insertion at the interface of the tunneling barrier and the free layer.

### CROSS-REFERENCE TO RELATED APPLICATIONS

The current application claims the benefit of and priority under 35 U.S.C. § 119(e) to U.S. Provisional Patent Application No. 62/608,506 entitled “Heterostructure for Electric Field Controlled Magnetic Tunnel Junctions,” filed Dec. 20, 2017. The disclosure of U.S. Provisional Patent Application No. 62/608,506 is hereby incorporated by reference in its entirety for all purposes.

### FIELD OF THE INVENTION

The present invention generally relates to materials allowing for the manipulation of the magnetic properties of magnetic heterostructures, and heterostructures made using such materials.

### BACKGROUND

Devices that rely on electricity and magnetism underlie much of modern electronics. Researchers have recently begun to develop and implement devices that take advantage of both electricity and magnetism in spin-electronic (or so-called “spintronic”) devices. These devices utilize quantum-mechanical magnetoresistance effects, such as giant magnetoresistance (“GMR”) and tunnel magnetoresistance (“TMR”). GMR and TMR principles regard how the resistance of a thin film structure that includes alternating layers of ferromagnetic and non-magnetic layers depends upon whether the magnetizations of ferromagnetic layers are in a parallel or antiparallel alignment. For example, magnetoresistive random-access memory (“MRAM”) is a technology that is being developed that typically utilizes TMR phenomena in providing for alternative random-access memory (“RAM”) devices. In a typical MRAM bit, data is stored in a magnetic structure that includes two ferromagnetic layers separated by an insulating layer—this structure is conventionally referred to as a magnetic tunnel junction (“MTJ”). The magnetization of one of the ferromagnetic layers (the fixed layer) is permanently set to a particular direction, while the other ferromagnetic layer (the free layer) can have its magnetization direction free to change. Generally, the MRAM bit can be written by manipulating the magnetization of the free layer such that it is either parallel or antiparallel with the magnetization of the fixed layer; and the bit can be read by measuring its resistance (since the resistance of the bit will depend on whether the magnetizations are in a parallel or antiparallel alignment).

MRAM technologies initially exhibited a number of technological challenges. The first generation of MRAM utilized the Oersted field generated from current in adjacent metal lines to write the magnetization of the free layer, which required a large amount of current to manipulate the magnetization direction of the bit's free layer when the bit size shrinks down to below 100 nm. Thermal assisted MRAM (“TA-MRAM”) utilizes heating of the magnetic layers in the MRAM bits above the magnetic ordering temperature to reduce the write field. This technology also requires high power consumption and long wire cycles. Spin transfer torque MRAM (“STT-MRAM”) utilizes the spin-polarized current exerting torque on the magnetization direction in order to reversibly switch the magnetization direction of the free layer.

### SUMMARY OF THE INVENTION

One embodiment includes a magnetic heterostructure including a stack including a plurality of magnetic and insulating layers and at least one seed/cap layer disposed adjacent to the stack, wherein the at least one seed/cap layer includes a material selected from the group of Ir, W, Mo, Ta, Pt, Hf, Re, Os, Ru, MgO, GdO, AlO, MgAlO, Mg, Cr, V, Mn, Bi, and Cu, and combinations thereof.

In another embodiment, the at least one seed/cap layer includes a material selected from the group of Ir/Mo, Ir/W, Ir/Cr, Cr/Ir, Ta/Mo, Ta/W, Ta/MgO, Cr/Mo, Cr/W, MgO/Cr, MgO/Ir, Mo/Ir/Mo, W/Ir/W, Mo/Ta/Mo, and W/Ta/W.

In a further embodiment, the magnetic heterostructure further includes an additional layer adjacent the seed/cap layer, wherein the additional layer includes a material selected from the group of MgO, GdO, AlO, MgAlO, and MgTiO.

In still another embodiment, the additional layer includes a hybrid material.

A still further embodiment includes a magnetic tunnel junction including a stack including a pinning layer, a reference layer, a tunneling layer, and a free layer, wherein the free layer includes a plurality of layers, wherein at least one of the plurality of layers includes a material selected from the group of Ir, W, Mo, Ta, Pt, Hf. Re, Os, Ru, MgO, Mg, Cr, V, Mn, Bi, Cu, and combinations thereof.

In yet another embodiment, at least two layers of the plurality of layers includes a material selected from the group of Ir, W, Mo, Ta, Pt, Hf, Re, Os, Ru, MgO, Mg, Cr, V, Mn, Bi, Cu, and combinations thereof.

In a yet further embodiment, the at least two layers are separated by at least one ferromagnetic layer.

In another additional embodiment, the at least one ferromagnetic layer includes a material selected from the group of CoFeB, CoFe, CoFeAl, CoB, and FeB.

In a further additional embodiment, wherein the flow of oxygen is controlled during deposition of the tunnel layer.

Another embodiment again includes a magnetic tunnel junction including a stack including a pinning layer, a reference layer, a tunneling layer, and a free layer and at least one insertion layer disposed between the tunneling layer and the free layer, wherein the insertion layer includes a material selected from the group of Ir, W, Mo, Ta, Pt, Hf, Re, Os, Ru, MgO, Mg, Cr, V, Mn, Gd, GdO, AlO, Al, and Bi.

In a further embodiment again, wherein the insertion layer includes two separate adjacent layers, wherein each of the two separate adjacent layers includes a material selected from the group of Ir, W, Mo, Ta, Pt, Hf, Re, Os, Ru, MgO, Mg, Cr, V, Mn, Gd, GdO, AlO, Al, and Bi.

In still yet another embodiment, the flow of oxygen is controlled during deposition of the tunnel layer.

A still yet further embodiment includes a magnetic tunnel junction including a stack including at least a pinning layer a reference layer, a tunneling layer, and a free layer and at least one insertion layer disposed between the tunneling layer and the free layer, wherein the at least one insertion layer includes a material selected from the group of Ir, W, Mo, Ta, Pt, Hf. Re, Os, Ru, MgO, Mg, Cr, V, Mn, Bi, and Cu, Gd, GdO, AlO, Al, and combinations thereof.

In still another additional embodiment, the magnetic tunnel junction further includes a seed layer, wherein the seed layer includes a material selected from the group of Ir, W, Mo, Ta, Pt, Hf, Re, Os, Ru, MgO, Mg, Cr, V, Mn, Bi, Cu, MgO, GdO, AlO, MgAlO, MgTiO, and combinations thereof.

In a still further additional embodiment, the flow of oxygen is controlled during deposition of the tunnel layer.

### BRIEF DESCRIPTION OF THE DRAWINGS

The description will be more fully understood with reference to the following figures and data graphs, which are presented as exemplary embodiments of the invention and should not be construed as a complete recitation of the scope of the invention.

FIG. 1 conceptually illustrates a schematic of a magnetic tunnel junction in accordance with an embodiment of the invention.

FIG. 2 conceptually illustrates a schematic of the voltage controlled magnetic anisotropy effect in accordance with an embodiment of the invention.

FIG. 3 conceptually illustrates a schematic of a voltage controlled magnetic anisotropy based precessional switching mechanism in accordance with an embodiment of the invention.

FIG. 4A conceptually illustrates an MEJ whereby the FM fixed layer and the FM free layer are separated by, and directly adjoined to, a dielectric layer in accordance with an embodiment of the invention.

FIG. 4B conceptually illustrates an MEJ with constituent cap/seed layers in accordance with an embodiment of the invention.

FIG. 5 conceptually illustrates an MEJ whereby the orientation of the magnetization directions is perpendicular to the plane of the constituent layers in accordance with an embodiment of the invention.

FIG. 6 conceptually illustrates an MEJ that includes multiple layers that work in aggregate to facilitate the functionality of the MEJ in accordance with an embodiment of the invention.

FIGS. 7A and 7B conceptually illustrate MEJs that include a semi-fixed layer in accordance with various embodiments of the invention.

FIGS. 8A and 8B conceptually illustrate how the application of a potential difference can reduce the coercivity of the free layer in accordance with various embodiments of the invention.

FIG. 9 conceptually illustrates using a metal line disposed adjacent to an FM free layer to generate spin-orbit torques that can impose a magnetization direction change on the FM free layer in accordance with an embodiment of the invention.

FIG. 10 conceptually illustrates the implementation of two MEJs that are housed within encapsulating layers and separated by field insulation in accordance with an embodiment of the invention.

FIG. 11 conceptually illustrates a schematic of a magnetic tunnel junction with hybrid seed layers in accordance with an embodiment of the invention.

FIGS. 12A to 12C conceptually illustrate schematics of magnetic tunnel junction with free layer insertions in accordance with various embodiments of the invention.

FIG. 13 conceptually illustrates a schematic of a magnetic tunnel junction with material insertion at the interface of the tunneling barrier and free layer in accordance with an embodiment of the invention.

FIG. 14 conceptually illustrates a magnetic tunnel junction with seed layers in accordance with an embodiment of the invention.

### DETAILED DESCRIPTION

Turning now to the drawings, magnetic heterostructures, magnetic layers, and related materials are illustrated. In various embodiments, magnetic heterostructures and magnetic layers can be implemented and configured to provide electric field controlled magnetic tunnel junctions. Such magnetic heterostructures and magnetic layers can incorporate a variety of different materials and layers for various effects. In many embodiments, the magnetic heterostructures incorporate hybrid seed layers. Such layers can be incorporated for various reasons including but not limited to producing an enhanced voltage controlled magnetic anisotropy (“VCMA”) effect. The VCMA effect can be explained in terms of the electric-field-induced change of occupancy of atomic orbitals at the interface, which, in conjunction with spin-orbit interaction, results in a change of anisotropy. In some embodiments, the magnetic heterostructures and layers incorporate free layer insertions. In a number of embodiments, the magnetic heterostructures incorporate a material insertion at the interface of the tunneling barrier and the free layer.

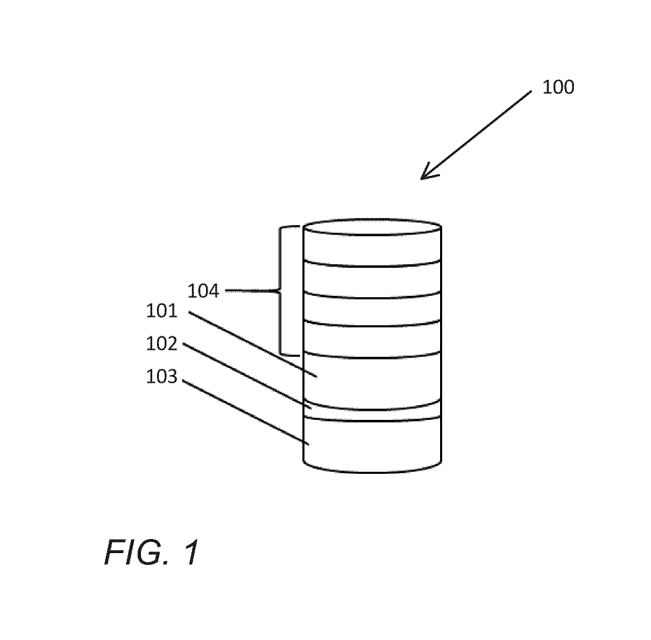

Many magnetic heterostructures in accordance with various embodiments of the invention are implemented in magnetic tunnel junctions. A typical device structure of a magnetic tunnel junction is conceptually illustrated in FIG. 1. As shown, the MTJ 100 includes a reference layer 101, a tunneling barrier 102, and a free layer 103. In many embodiments, the reference layer 101 is composed of a hard magnetic material, the tunneling barrier 102 is composed of an insulating material, and the free layer 103 is composed of a soft (relative to the reference) magnetic material. In the illustrative embodiment, the MTJ 100 further includes a pinning layer 104. Typically, the pinning layer 104 is composed of multiple materials to create a hard magnet in order to pin (fix) the orientation of the reference layer 101.

If the magnetic orientation of the reference and fixed layers are in the same direction, the device will have a low resistance, denoted as RP, whereas if their orientations are in opposite directions, the device will have a high resistance, denoted as RAP. There are currently multiple mechanisms to switch the magnetic orientation of the free layer: via the application of an external field; via the spin-transfer-torque (i.e., spin torque-transfer, or STT) mechanism, whereby a polarized current applies a significant spin-based torque to the free layer's magnetic orientation; and lastly by the modulation of the interfacial anisotropy within the free layer via an electric field. This last mechanism is referred to as the VCMA effect.

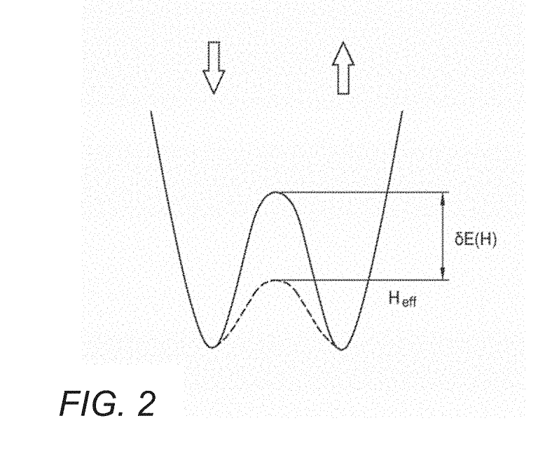

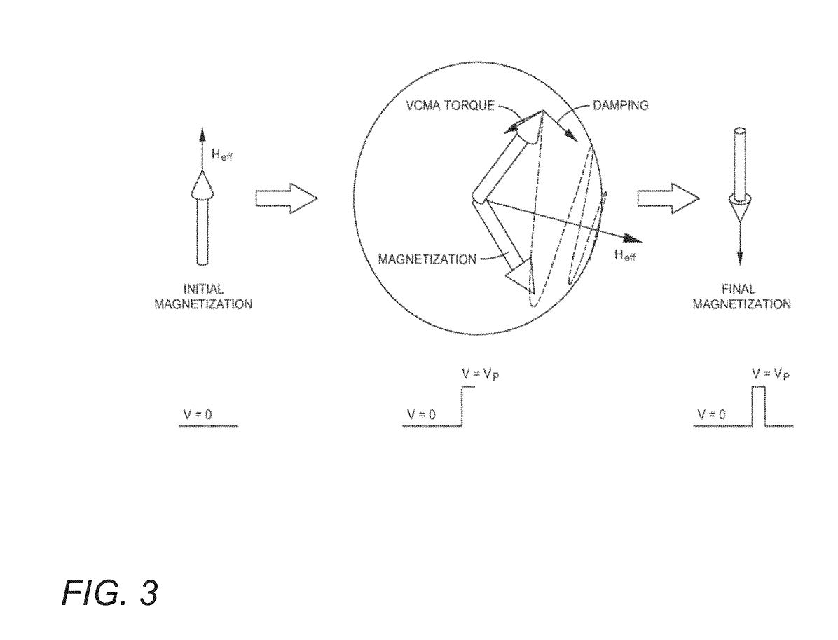

The VCMA effect is conceptually illustrated in FIG. 2. In the illustrative embodiment, H_{eff} refers to the effective magnetic anisotropy field of the free layer, and δE(H) refers to the change of perpendicular magnetic anisotropy (“PMA”)—i.e., the energy barrier E(H) when an electric field, functionally a voltage, is applied across the MTJ. One possible way for the utilization of the effect for switching is illustrated in FIG. 3. When an electric field, functionally a voltage across the MTJ, is applied to the free layer, the interfacial perpendicular magnetic anisotropy at the free layer can be modulated—i.e., the energy barrier producing a PMA can be increased or decreased. To utilize this effect for switching, a perpendicularly oriented MTJ can be used. In steady-state—i.e., zero voltage applied—the PMA producing energy barrier can lead to the free layer having a perpendicular to plane (also referred to as out-of-plane, denoted as OOP) magnetic orientation, either in the up or down direction. By applying a voltage bias such that the PMA (energy barrier) is reduced to near zero, the magnetization of the free layer can begin to precess in order to align with an in-plane (“IP”) direction. As the precession occurs, the magnetization can swing into the opposite OOP direction and continue to swing back into the original direction, all the while the precession angle about the IP direction decreases. If the voltage bias is removed at a time when the magnetization is in the opposite OOP direction from the original, the PMA can return to the steady-state condition and the free layer can now be aligned in the opposite OOP direction as before the voltage application. This mechanism can be used to toggle the free layer. (See, e.g., US Patent Pub. Nos. US/2014/0124882A1, US/2014/0177327A1, US/2014/0124882A1, and U.S. Pat. No. 8.841,739, the disclosures of which are incorporated herein by reference.)

MTJs in accordance with various embodiments of the invention can be implemented with a magnetoelectric junction (“MEJ”) structure. In this disclosure, the term “magnetoelectric junction” is used to refer to devices that are configured to viably use VCMA principles to help them realize two distinct information states—e.g., voltage-controlled magnetic anisotropy-based MTJs (“VMTJs”) and VCMA switches. MTJs, MEJs, and magnetic heterostructures and magnetic layers for electric field controlled magnetic tunnel junctions are discussed below in further detail.

### Fundamental Magnetoelectric Junction Structures

A fundamental MEJ structure typically includes a ferromagnetic (“FM”) fixed layer, a FM free layer that has a uniaxial anisotropy (for simplicity, the terms “FM fixed layer” and “fixed layer” will be considered equivalent throughout this application, unless otherwise stated; similarly, the terms “FM free layer”, “ferromagnetic free layer,” “free layer that has a uniaxial anisotropy”, and “free layer” will also be considered equivalent throughout this application, unless otherwise stated), and a dielectric layer separating the FM fixed layer and FM free layer. Generally, the FM fixed layer has a fixed magnetization direction—i.e., the direction of magnetization of the FM fixed layer does not change during the normal operation of the MEJ. Conversely, the FM free layer can adopt a magnetization direction that is either substantially parallel with or antiparallel with the FM fixed layer—i.e., during the normal operation of the MEJ, the direction of magnetization can be made to change. For example, the FM free layer may have a magnetic uniaxial anisotropy, whereby it has an easy axis that is substantially aligned with the direction of magnetization of the FM fixed layer. The easy axis refers to the axis, along which the magnetization direction of the layer prefers to align. In other words, an easy axis is an energetically favorable direction (axis) of spontaneous magnetization that is determined by various sources of magnetic anisotropy including, but not limited to, magnetocrystalline anisotropy, magnetoelastic anisotropy, geometric shape of the layer, etc. Relatedly, an easy plane is a plane whereby the direction of magnetization is favored to be within the plane, although there is no bias toward a particular axis within the plane. The easy axis and the direction of the magnetization of the fixed layer can be considered to be ‘substantially aligned’ when—in the case where the magnetization direction of the free layer conforms to the easy axis—the underlying principles of magnetoresistance take effect and result in a distinct measurable difference in the resistance of the MEJ as between when the magnetization directions of the FM layers are substantially parallel relative to when they are substantially antiparallel, e.g. such that two distinct information states can be defined. Similarly, the magnetization directions of the fixed layer and the free layer can be considered to be substantially parallel/antiparallel when the underlying principles of magnetoresistance take effect and result in a distinct measurable difference in the resistance of the MEJ as between the two states (i.e., substantially parallel and substantially antiparallel).

VCMA phenomena can be relied on in switching the FM free layer's characteristic magnetization direction—i.e., the MEJ can be configured such that the application of a potential difference across the MEJ can reduce the coercivity of the free layer, which can allow the free layer's magnetization direction to be switched more easily. For example, with a reduced coercivity, the FM free layer can be subject to magnetization that can make it substantially parallel with or substantially antiparallel with the direction of the magnetization for the FM fixed layer. A more involved discussion regarding the general operating principles of an MEJ is presented in the following section.

Notably, the magnetization direction, and the related characteristics of magnetic anisotropy, can be established for the FM fixed and FM free layers using any suitable method. For instance, the shapes of the constituent FM fixed layer, FM free layer, and dielectric layer, can be selected based on desired magnetization direction orientations. For example, implementing FM fixed, FM free, and dielectric layers that have an elongated shape (e.g., an elliptical cross-section) may tend to induce magnetic anisotropy that is in the direction of the length of the elongated axis—i.e., the FM fixed and FM free layers will possess a tendency to adopt a direction of magnetization along the length of the elongated axis. In other words, the direction of the magnetization is ‘in-plane’. Alternatively, where it is desired that the magnetic anisotropy have a directional component that is perpendicular to the FM fixed and FM free layers (i.e., ‘out-of-plane’), the shape of the layers can be made to be symmetrical, e.g. circular, and further the FM layers can be made to be thin. In this case, while the tendency of the magnetization to remain in-plane may still exist, it may not have a preferred directionality within the plane of the layer. Because the FM layers are relatively thinner, the anisotropic effects that result from interfaces between the FM layers and any adjacent layers, which tend to be out-of-plane, may tend to dominate the overall anisotropy of the FM layer. Alternatively, a material may be used for the FM fixed or free layers which has a bulk perpendicular anisotropy—i.e., an anisotropy originating from its bulk (volume) rather than from its interfaces with other adjacent layers. The FM free or fixed layers may also consist of a number of sub-layers, with the interfacial anisotropy between individual sub-layers giving rise to an effective bulk anisotropy to the material as a whole. Additionally, FM free or fixed layers may be constructed which combine these effects, and for example have both interfacial and bulk contributions to perpendicular anisotropy. Of course, any suitable methods for imposing magnetic anisotropy can be implemented in accordance with many embodiments of the invention.

While MEJs demonstrate much promise, their potential applications continue to be explored. For example, U.S. Pat. No. 8,841,739 to Khalili Amiri et al. discloses DIOMEJ cells that utilize diodes (e.g. as opposed to transistors) as access devices to MEJs. As discussed in the '739 patent, using diodes as access devices for MEJs can confer a number of advantages and thereby make the implementation of MEJs much more practicable. The disclosure of U.S. Pat. No. 8,841,739 is hereby incorporated by reference in its entirety, especially as it pertains to implementing diodes as access devices for MEJs. Furthermore, U.S. Pat. No. 9,099,641 to Khalili Amiri et al. discloses MEJ configurations that demonstrate improved writeability and readability, and further make the implementation of MEJs more practicable. The disclosure of U.S. Pat. No. 9,099,641 is hereby incorporated by reference in its entirety, especially as it pertains to MEJ configurations that demonstrate improved writeability and readability. Additionally, U.S. patent application Ser. No. 14/681,358 to Qi Hu discloses implementing MEJ configurations that incorporate piezoelectric materials to strain the respective MEJs during operation, and thereby improve performance. The disclosure of U.S. patent application Ser. No. 14/681,358 is hereby incorporated by reference in its entirety, especially as it pertains to MEJ configurations that incorporate elements configured to strain the respective MEJs during operation, and thereby improve performance.

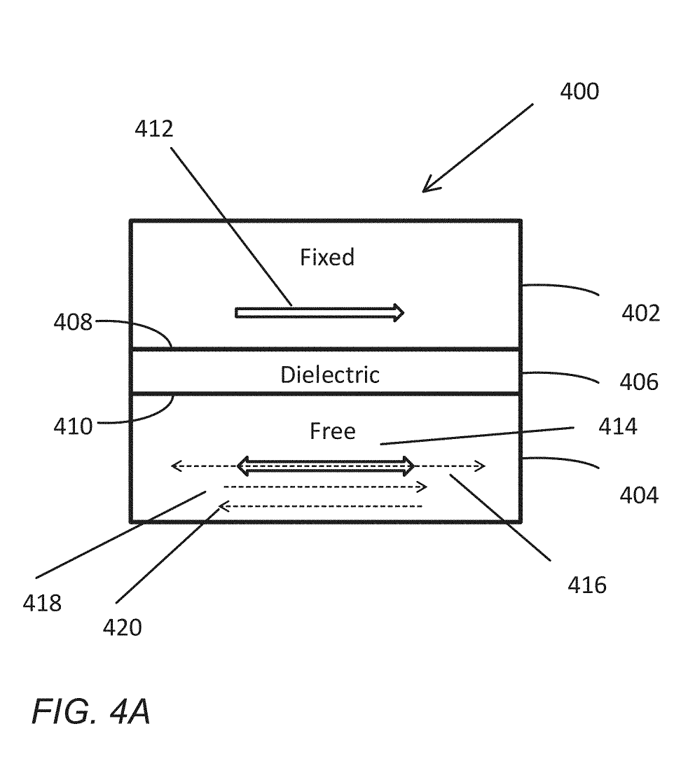

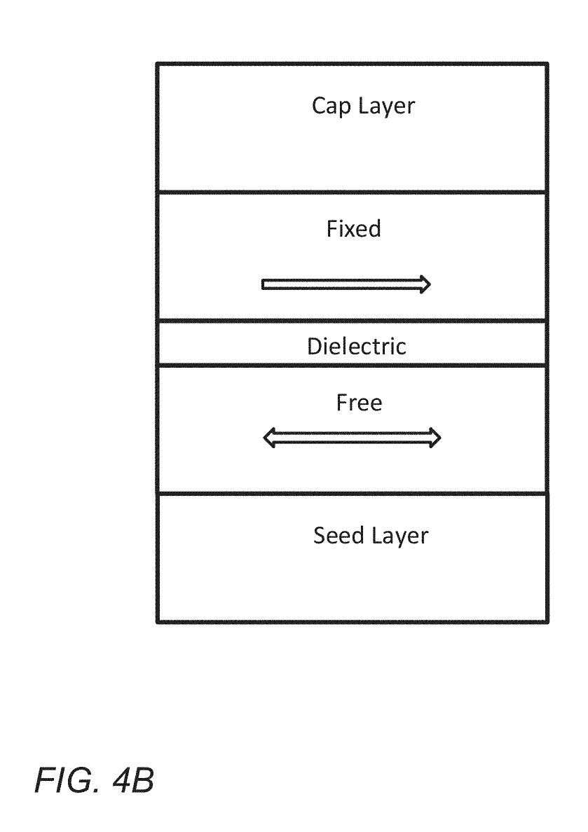

FIG. 4A conceptually illustrates an MEJ whereby the FM fixed layer and the FM free layer are separated by, and directly adjoined to, a dielectric layer. In particular, in the illustration, the MEJ 400 includes an FM fixed layer 402 that is adjoined to a dielectric layer 406, thereby forming a first interface 408; the MEJ further includes an FM free layer 404 that is adjoined to the dielectric layer 406 on an opposing side of the first interface 408, and thereby forms a second interface 410. The MEJ 400 has an FM fixed layer 402 that has a magnetization direction 412 that is in-plane, and depicted in the illustration as being from left to right. Accordingly, the FM free layer is configured such that it can adopt a magnetization direction 414 that is either parallel with or antiparallel with the magnetization direction of the FM fixed layer. For reference, the easy axis 416 is illustrated, as well as a parallel magnetization direction 418, and an antiparallel magnetization direction 420. Additional contacts (capping or seed materials, or multilayers of materials, not shown in FIG. 4A) may be attached to the FM free layer 404 and the FM fixed layer 402, thereby forming additional interfaces. FIG. 4B conceptually illustrates an MEJ and depicts the constituent cap/seed layers. The contacts can both contribute to the electrical and magnetic characteristics of the device by providing additional interfaces, and can also be used to apply a potential difference across the device. Additionally, it should of course be understood that MEJs can include metallic contacts that can allow them to interconnect with other electrical components.

Importantly, by appropriately selecting the materials, the MEJ can be configured such that the application of a potential difference across the FM fixed layer and the FM free layer can modify the magnetic anisotropy, and correspondingly reduce the coercivity, of the FM free layer. For example, whereas in FIGS. 4A and 4B, the magnetization direction of the FM free layer is depicted as being in-plane, the application of a voltage may distort the magnetization direction of the FM free layer such that it includes a component that is at least partially out of plane. The particular dynamics of the modification of the magnetic anisotropy will be discussed below in the section entitled “General Principles of MEJ Operation.” Suitable materials for the FM layers such that this effect can be implemented include iron, nickel, manganese, cobalt, FeCoB, FeGaB, FePd, FePt; further, any compounds or alloys that include these materials may also be suitable. Suitable materials for the dielectric layer include MgO and Al₂O₃. Of course, it should be understood that the material selection is not limited to those recited—any suitable FM material can be used for the FM fixed and free layers and any suitable material can be used for the dielectric layer. It should also be understood that each of the FM free layer, FM fixed layer, and dielectric layer may consist of a number of sub-layers, which acting together provide the functionality of the respective layer.

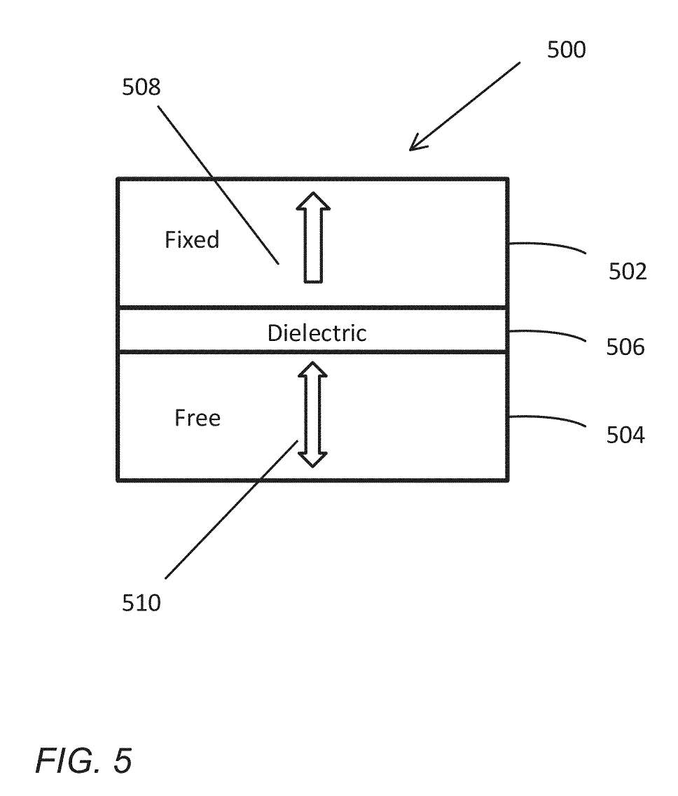

FIG. 5 conceptually illustrates an MEJ whereby the orientation of the magnetization directions is perpendicular to the plane of the constituent layers (“perpendicular magnetic anisotropy”). In particular, the MEJ 500 is similarly configured to that seen in FIG. 4A, with an FM fixed layer 502 and an FM free layer 504 adjoined to a dielectric layer 506. However, unlike the MEJ in FIG. 4A, the magnetization directions of the FM fixed and FM free layers, 508 and 510 respectively, are oriented perpendicularly to the layers of the MEJ. Additional contacts (capping or seed materials, or multilayers of materials, not shown) may be attached to the FM free layer 504 and the FM fixed layer 502, thereby forming additional interfaces. The contacts both contribute to the electrical and magnetic characteristics of the device by providing additional interfaces, and can also be used to apply a potential difference across the device. It should also be understood that each of the FM free layer, FM fixed layer, and dielectric layer may consist of a number of sub-layers, which acting together provide the functionality of the respective layer.

Of course, it should be understood that the direction of magnetization for the FM layers can be in any direction, as long as the FM free layer can adopt a direction of magnetization that is either substantially parallel with or antiparallel with the direction of magnetization of the FM fixed layer. For example, the direction of magnetization can include both in-plane and out-of-plane components.

In many instances, an MEJ includes additional adjunct layers that function to facilitate the operation of the MEJ. For example, in many instances, the FM free layer includes a capping or seed layer, which can (1) help induce greater electron spin perpendicular to the surface of the layer, thereby increasing its perpendicular magnetic anisotropy, and/or (2) can further enhance the sensitivity to the application of an electrical potential difference. In general, the seed/cap layers can beneficially promote the crystallinity of the ferromagnetic layers. The seed layer can also serve to separate a corresponding ferromagnetic layer from an ‘underlayer.’ As will be discussed below, in many embodiments of the invention, the capping/seed layer includes one of: Hf, Mo, W, Ir, Bi, Re, and/or Au; the listed elements can be incorporated by themselves, in combination with one another, or in combination with more conventional materials, such as Ta, Ru, Pt, Pd. As will be discussed in greater detail below, seed and/or cap layers made in this way can confer a number of benefits to the MEJ structure.

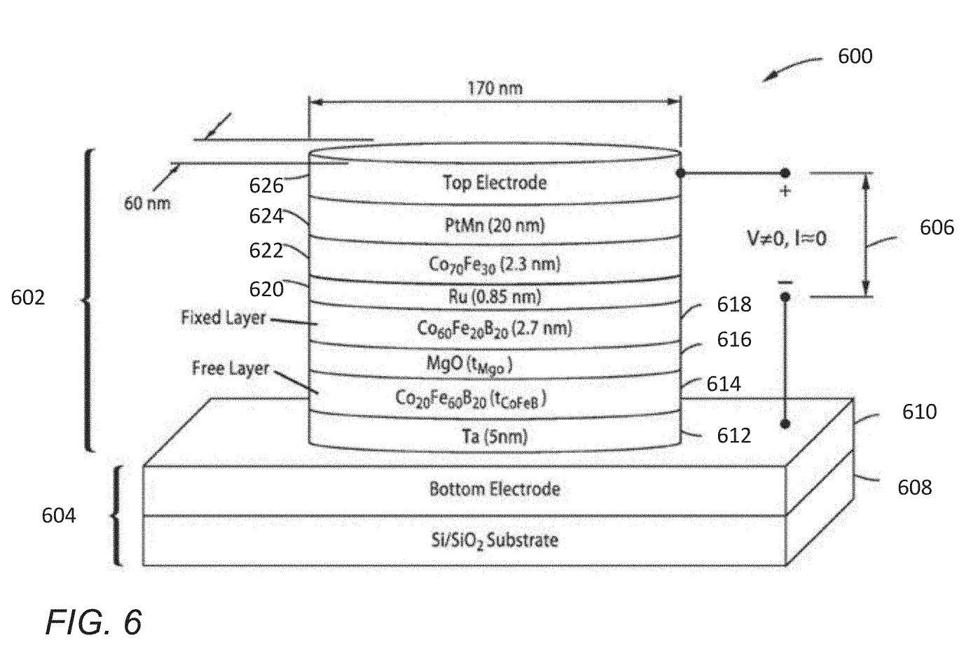

FIG. 6 conceptually illustrates an MEJ 600 that includes multiple layers that work in aggregate to facilitate the functionality of the MEJ 600. A pillar section 602 extends from a planar section 604. A voltage is shown being applied 606 between the top and bottom of the pillar. By way of example, the planar section 604 includes an Si/SiO₂ substrate 608 adjoined to a bottom electrode 610. In the illustrated embodiment, the pillar 602 includes the following layers in order: Ta 612 (e.g., 5 nm in thickness); a free layer 614 having an Fe-rich CoFeB material (e.g., Co₂₀Fe₆₀B₂₀ having a thickness generally ranging from, but not limited to, 0.8 nm-1.6 nm); a dielectric layer 616 having a dielectric oxide such as MgO or Al₂O₃ having a thickness of approximately, but not limited to, 0.8-1.4 nm); a FM fixed layer 618 having a CoFeB material (e.g., Co₆₀Fe₂₀B₂₀ having a thickness of approximately, but not limited to, 2.7 nm); a metal layer (e.g. Ru 620 having a thickness of approximately, but not limited to, 0.85 nm) to provide antiferromagnetic inter-layer exchange coupling; an exchange-biased layer 622 of Co₇₀Fe₃₀ (e.g., thickness of approximately, but not limited to, 2.3 nm), the magnetization orientation of which is pinned by exchange bias using an anti-ferromagnetic layer 624 (e.g., PtMn, IrMn, or a like material having a thickness of approximately, but not limited to, 20 nm); and a top electrode 626. By way of example and not limitation, the pillar of the device depicted is in the shape of a 170 nm×60 nm elliptical nanopillar. In this illustration, Ta layer 612 is used as a seed layer to help induce a larger magnitude of perpendicular magnetic anisotropy and/or enhance the electric-field sensitivity of magnetic properties (such as anisotropy) in the FM free layer. It also acts as a sink of B atoms during annealing of the material stack after deposition, resulting in better crystallization of the FM free layer and thereby increasing the TMR and/or VCMA effect. Of course, any suitable materials can be used as a capping or seed layer 612; for example, as will be discussed in greater detail below, in many embodiments of the invention, the seed and/or cap layers include one of: Mo, W, Hf, Ir, Bi, Rh, and/or Au. More generally, any adjunct layers that can help facilitate the proper functioning of the MEJ can be implemented in an MEJ.

MEJs can also include a semi-fixed layer, which has a magnetic anisotropy that is altered by the application of a potential difference. In many instances, the characteristic magnetic anisotropy of the semi-fixed layer is a function of the applied voltage. For example, in many cases, the direction of the magnetization of the semi-fixed layer is oriented in the plane of the layer in the absence of a potential difference across the MEJ. However, when a potential difference is applied, the magnetic anisotropy is altered such that the magnetization includes a strengthened out-of-plane component. Moreover, the extent to which the magnetic anisotropy of the semi-fixed layer is modified as a function of applied voltage can be made to be less than the extent to which the magnetic anisotropy of the FM free layer is modified as a function of applied voltage. The incorporation of a semi-fixed layer can facilitate a more nuanced operation of the MEJ (to be discussed below in the section entitled “General Principles of MEJ Operation”).

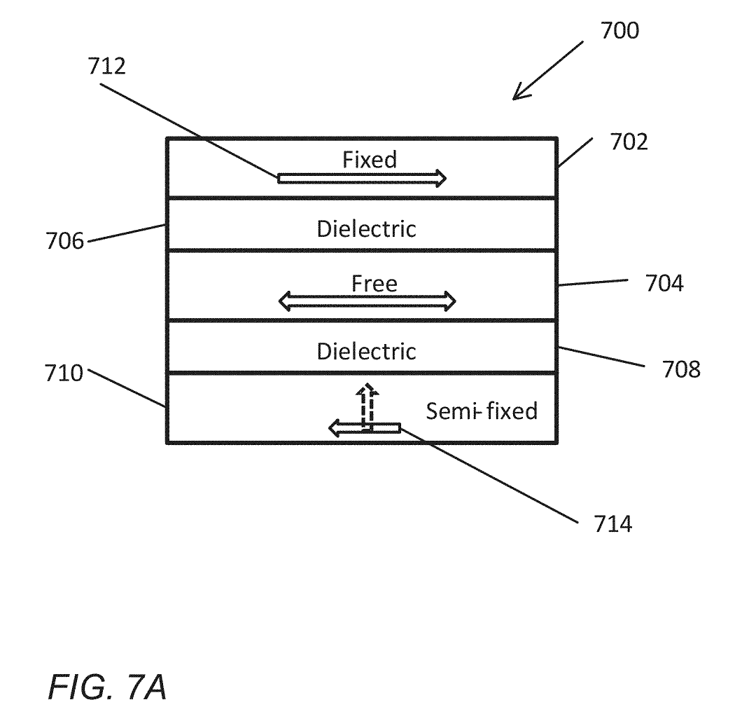

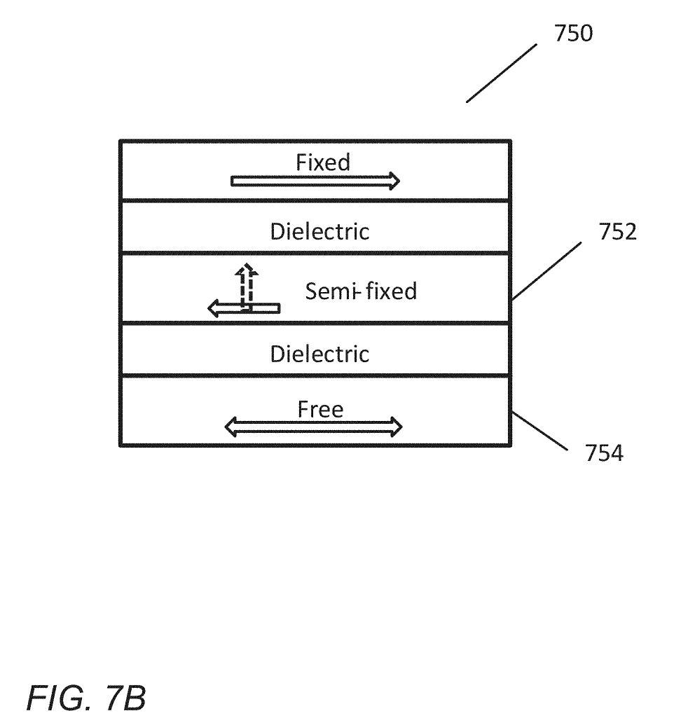

FIG. 7A conceptually illustrates an MEJ that includes a semi-fixed layer in accordance with an embodiment of the invention. In particular, the configuration of the MEJ 700 is similar to that depicted in FIG. 4A, insofar as it includes an FM fixed layer 702 and an FM free layer 704 separated by a dielectric layer 706. However, the MEJ 700 further includes a second dielectric layer 708 adjoined to the FM free layer 704 such that the FM free layer 704 is adjoined to two dielectric layers, 706 and 708 respectively, on opposing sides. Further, a semi-fixed layer 710 is adjoined to the dielectric layer. Typically, the direction of magnetization of the semi-fixed layer 714 is antiparallel with that of the FM fixed layer 712. As mentioned above, the direction of magnetization of the semi-fixed layer can be manipulated based on the application of a voltage. In the illustration, it is depicted that the application of a potential difference adjusts the magnetic anisotropy of the semi-fixed layer such that the strength of the magnetization along a direction orthogonal to the initial direction of magnetization (in this case, out of the plane of the layer) is developed. It should of course be noted that the application of a potential difference can augment the magnetic anisotropy in any number of ways; for instance, in some MEJs, the application of a potential difference can reduce the strength of the magnetization in a direction orthogonal to the initial direction of magnetization. Note also that in the illustration, the directions of magnetization are all depicted to be in-plane where there is no potential difference. However, of course it should be understood that the direction of the magnetization can be in any suitable direction. More generally, although a particular configuration of an MEJ that includes a semi-fixed layer is depicted, it should of course be understood that a semi-fixed layer can be incorporated within an MEJ in any number of configurations. For example, FIG. 7B conceptually illustrates an MEJ that includes a semi-fixed layer that is in a different configuration than that seen in 7A. In particular, the MEJ 750 is similar to that seen in FIG. 7A, except that the positioning of the semi-fixed layer 752 and the free layer 754 is inverted. In certain situations, such a configuration may be more desirable. The general principles of the operation of an MEJ are now discussed.

### General Principles of MEJ Operation

MEJ operating principles—as they are currently understood—are now discussed. Note that embodiments of the invention are not constrained to the particular realization of these phenomena. Rather, the presumed underlying physical phenomena is being presented to inform the reader as to how MEJs are believed to operate. MEJs generally function to achieve two distinct states using the principles of magnetoresistance. As mentioned above, magnetoresistance principles regard how the resistance of a thin film structure that includes alternating layers of ferromagnetic and non-magnetic layers depends upon whether the ferromagnetic layers are in a substantially parallel or antiparallel alignment. Thus, an MEJ can achieve a first state where its FM layers have magnetization directions that are substantially parallel, and a second state where its FM layers have magnetization directions that are substantially antiparallel. MEJs further rely on voltage-controlled magnetic anisotropy phenomena. Generally, VCMA phenomena regard how the application of a voltage to a ferromagnetic material that is adjoined to an adjacent dielectric layer can impact the characteristics of the ferromagnetic material's magnetic anisotropy. For example, it has been demonstrated that the interface of oxides such as MgO with metallic ferromagnets such as Fe, CoFe, and CoFeB can exhibit a large perpendicular magnetic anisotropy which is furthermore sensitive to voltages applied across the dielectric layer, an effect that has been attributed to spin-dependent charge screening, hybridization of atomic orbitals at the interface, and to the electric field induced modulation of the relative occupancy of atomic orbitals at the interface. MEJs can exploit this phenomenon to achieve two distinct states. For example, MEJs can employ one of two mechanisms to do so: first, MEJs can be configured such that the application of a potential difference across the MEJ functions to reduce the coercivity of the FM free layer, such that it can be subject to magnetization in a desired magnetic direction, e.g. either substantially parallel with or antiparallel with the magnetization direction of the fixed layer; second, MEJ operation can rely on precessional switching (or resonant switching), whereby by precisely subjecting the MEJ to voltage pulses of precise duration, the direction of magnetization of the FM free layer can be made to switch.

In many instances, MEJ operation is based on reducing the coercivity of the FM free layer such that it can adopt a desired magnetization direction. With a reduced coercivity, the FM free layer can adopt a magnetization direction in any suitable way. For instance, the magnetization can result from: an externally applied magnetic field, the magnetic field of the FM fixed layer; the application of a spin-transfer torque (“STT”) current; the magnetic field of a FM semi-fixed layer; the application of a current in an adjacent metal line inducing a spin-orbit torque (“SOT”); and any combination of these mechanisms, or any other suitable method of magnetizing the FM free layer with a reduced coercivity.

By way of example and not limitation, examples of suitable ranges for the externally applied magnetic field are in the range of 0 to 100 Oe. The magnitude of the electric field applied across the device to reduce its coercivity or bring about resonant switching can be approximately in the range of 0.1-2.0 V/nm, with lower electric fields required for materials combinations that exhibit a larger VCMA effect. The magnitude of the STT current used to assist the switching may be in the range of approximately 0.1-1.0 MA/cm².

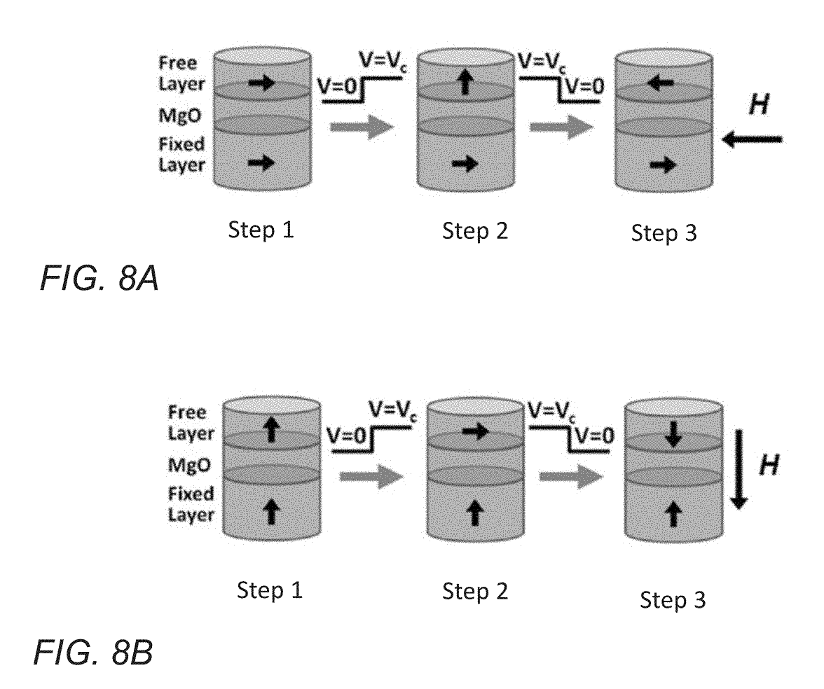

FIG. 8A depicts how the application of a potential difference can reduce the coercivity of the free layer such that an externally applied magnetic field H can impose a magnetization switching on the free layer. In the illustration, in step 1, the FM free layer and the FM fixed layer have a magnetization direction that is substantially in plane; the FM free layer has a magnetization direction that is parallel with that of the FM fixed layer. Further, in Step 1, the coercivity of the FM free layer is such that the FM free layer is not prone to having its magnetization direction reversed by the magnetic field H, which is in a direction antiparallel with the magnetization direction of the FM fixed layer. However, a voltage V_{c} is then applied, which results in step 2, where the voltage V_{c} has magnified the perpendicular magnetization direction component of the free layer (out of its plane). Correspondingly, the coercivity of the FM free layer is reduced such that it is subject to magnetization by an in-plane magnetic field H. Accordingly, when the potential difference V_{c} is removed, VCMA effects are removed and the magnetic field H, which is substantially anti-parallel to the magnetization direction of the FM fixed layer, causes the FM free layer to adopt a direction of magnetization that is antiparallel with the magnetization direction of the FM fixed layer. Hence, as the MEJ now includes an FM fixed layer and an FM free layer that have magnetization directions that are antiparallel, it reads out a second information state (resistance value) different from the first. In general, it should be understood that in many embodiments where the magnetization directions of the free layer and the fixed layer are substantially in-plane, the application of a voltage enhances the perpendicular magnetic anisotropy such that the FM free layer can be caused to adopt an out-of-plane direction of magnetization. Stated differently, the magnetoelectric junction is configured such that when a potential difference is applied across the magnetoelectric junction, the magnetic anisotropy of the ferromagnetic free layer is altered such that the relative strength of the magnetic anisotropy along a second easy axis that is orthogonal to the first easy axis (which corresponds to the magnetization direction of the fixed layer), or the easy plane where there is no easy axis that is orthogonal to the first easy axis, as compared to the strength of the magnetic anisotropy along the first easy axis, is magnified or reduced for the duration of the application of the potential difference. The magnetization direction can thereby be made to switch. In general, it can be seen that by controlling the potential difference and the direction of an applied external magnetic field, an MEJ switch can be achieved.

It should of course be understood that the direction of the FM fixed layer's magnetization direction need not be in-plane—it can be in any suitable direction. For instance, it can be substantially out of plane. Additionally, the FM free layer can include both in-plane and out-of-plane magnetic anisotropy directional components. FIG. 8B depicts a corresponding case relative to FIG. 8A when the FM fixed and FM free layers have magnetization directions that are perpendicular to the layers of the MEJ (out-of-plane). It is of course important, that an FM, magnetically anisotropic, free layer be able to adopt a magnetization direction that is either substantially parallel with an FM fixed layer, or substantially antiparallel with an FM fixed layer. In other words, when unburdened by a potential difference, the FM free layer can adopt a direction of magnetization that is either substantially parallel with or antiparallel with the direction of the FM fixed layer's magnetization, to the extent that a distinct measurable difference in the resistance of the MEJ that results from the principles of magnetoresistance as between the two states (i.e., parallel alignment vs. antiparallel alignment) can be measured, such that two distinct information states can be defined.

Note of course that the application of an externally applied magnetic field is not the only way for the MEJ to take advantage of reduced coercivity upon application of a potential difference. For example, the magnetization of the FM fixed layer can be used to impose a magnetization direction on the free layer when the free layer has a reduced coercivity. Moreover, an MEJ can be configured to receive a spin-transfer torque current when application of a voltage causes a reduction in the coercivity of the FM free layer. Generally, STT current is a spin-polarized current that can be used to facilitate the change of magnetization direction on a ferromagnetic layer. It can originate, for example, from a current passed directly through the MEJ device, such as due to leakage when a voltage is applied, or it can be created by other means, such as by spin-orbit-torques (e.g., Rashba or Spin-Hall Effects) when a current is passed along a metal line placed adjacent to the FM free layer. Accordingly, the spin orbit torque current can then help cause the FM free layer to adopt a particular magnetization direction, where the direction of the spin orbit torque determines the direction of magnetization. This configuration is advantageous over conventional STT-RAM configurations since the reduced coercivity of the FM free layer reduces the amount of current required to cause the FM free layer to adopt a particular magnetization direction, thereby making the device more energy efficient.

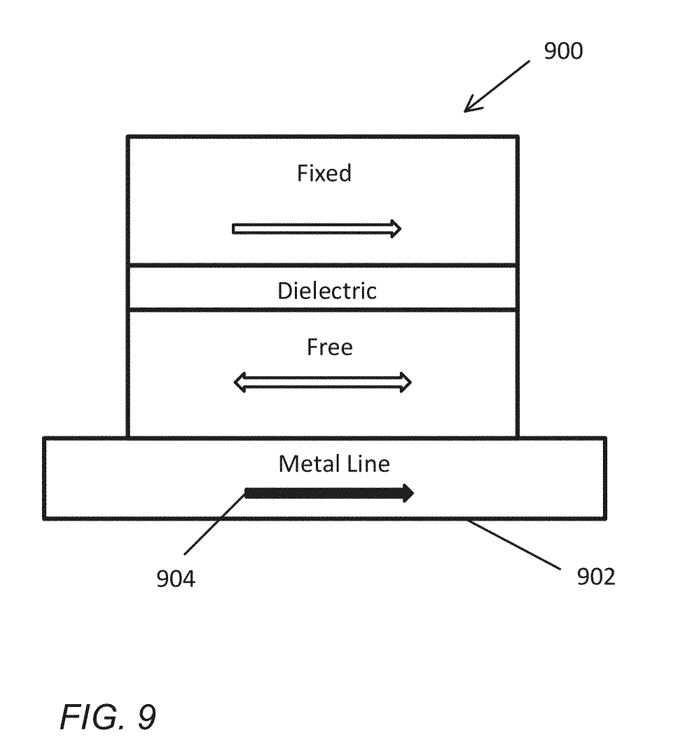

FIG. 9 depicts using a metal line disposed adjacent to an FM free layer to generate spin-orbit torques that can impose a magnetization direction change on the FM free layer. In particular, the MEJ 900 is similar to that seen in FIG. 4A, except that it further includes a metal line 902, whereby a current 904 can flow to induce spin-orbit torques, which can thereby help impose a magnetization direction change on the ferromagnetic free layer.

Additionally, in many instances, an MEJ cell can further take advantage of thermally assisted switching (“TAS”) principles. Generally, in accordance with TAS principles, heating up the MEJ during a writing process reduces the magnetic field required to induce switching. Thus, for instance, where STT is employed, even less current may be required to help impose a magnetization direction change on a free layer, particularly where VCMA principles have been utilized to reduce its coercivity.

Moreover, the switching of MEJs to achieve two information states can also be achieved using voltage pulses. In particular, if voltage pulses are imposed on the MEJ for a time period that is one-half of the precession of the magnetization of the free layer, then the magnetization may invert its direction. Using this technique, ultrafast switching times (e.g., below 1 ns) can be realized; moreover, using voltage pulses as opposed to a current, makes this technique more energetically efficient as compared to the precessional switching induced by STT currents, as is often used in STT-RAM. However, this technique is subject to the application of a precise pulse that is half the length of the precessional period of the magnetization layer. For instance, it has been observed that pulse durations in the range of 0.05 to 3 nanoseconds can reverse the magnetization direction. Additionally, the voltage pulse must be of suitable amplitude to cause the desired effect—e.g., reverse the direction of magnetization.

Based on this background, it can be seen that MEJs can confer numerous advantages relative to conventional MTJs. For example, they can be controlled using voltages of a single polarity—indeed, the '739 patent, incorporated by reference above, discusses using diodes, in lieu of transistors, as access devices to the MEJ, and this configuration is enabled because MEJs can be controlled using voltage sources of a single polarity.

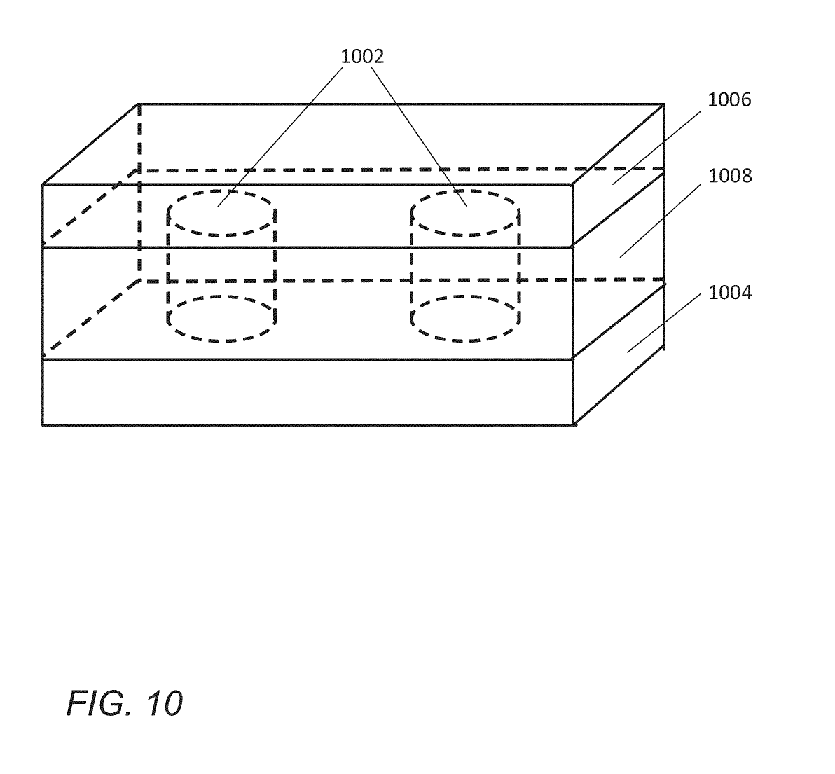

Note that while the above discussion largely regards the operation of single MEJs, it should of course be understood that in many instances, a plurality of MEJs are implemented together. For example, the '671 patent application discloses MeRAM configurations that include a plurality of MEJs disposed in a cross-bar architecture. It should be clear that MEJ systems can include a plurality of MEJs in accordance with embodiments of the invention. Where multiple MEJs are implemented, they can be separated by field insulation, and encapsulated by top and bottom layers. Thus, for example, FIG. 10 depicts the implementation of two MEJs that are housed within encapsulating layers and separated by field insulation. In particular, the MEJs 1002 are encapsulated within a bottom layer 1004 and a top layer 1006. Field insulation 1008 is implemented to isolate the MEJs and facilitate their respective operation. It should of course be appreciated that each of the top and bottom layers can include one or multiple layers of materials/structures. As can also be appreciated, the field insulation material can be any suitable material that functions to facilitate the operation of the MEJs in accordance with embodiments of the invention. While a certain configuration for the implementation of a plurality of MEJs has been illustrated and discussed, any suitable configuration that integrates a plurality of MEJs can be implemented in accordance with embodiments of the invention.

### MTJs Incorporating Hybrid/Alloy Seed Layers

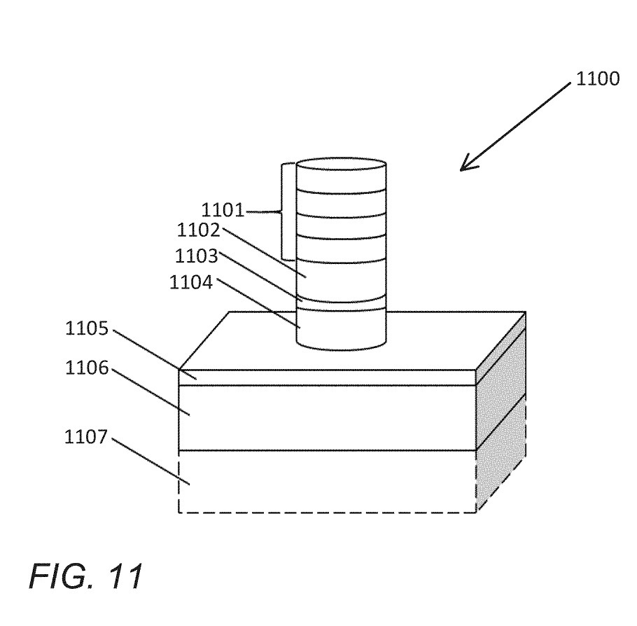

MTJs in accordance with various embodiments of the invention can be implemented and configured to incorporate various materials and layer(s) of such materials. Many embodiments include an MTJ incorporating a hybrid seed material. FIG. 11 conceptually illustrates such an MTJ. As shown, the MTJ 1100 includes a pinning layer 1101, a reference layer 1102, a tunneling layer 1103, a free layer 1104, a layer of thin material 1105 of the seed layer, and a layer of main material 1106 of the seed layer. The various layers can be made of many different types of materials. For example, in some embodiments, the reference layer 1102 and free layer 1104 can include material such as but not limited to CoFeB, CoFe, CoFeAl, CoB, and FeB. The tunneling layer 1103 can include material such as but not limited to MgO and AlO. The pinning layer 1101 can include but is not limited to multiple repetitions of Co/Pt, Co/Pd, and Co/Ni.

In the illustrative embodiment of FIG. 11, layers 1105 and 1106 are the proposed hybrid layers (seed/cap layers) that can be configured to produce an enhanced VCMA effect. Examples of the materials for layers 1105 and 1106 can include but are not limited to Ir, W, Mo, Ta, Pt, Hf, Re, Os, Ru, MgO, Mg, Cr, V, Mn, Bi, Cu, etc. Examples of combinations for layer 1106/1105 compositions can include but are not limited to Ir/Mo, Ir/W, Ir/Cr, Cr/Ir, Ta/Mo, Ta/W, Ta/MgO, Cr/Mo, Cr/W, MgO/Cr, etc. In many cases, the first layer is an element with properties promoting VCMA while the thin layer next to the free layer is a diffusion barrier which itself also has properties for promoting VCMA. The combination of both layers can also be used to promote a particular crystal orientation and lattice constant within the free layer. In some embodiments, an additional layer can optionally be added to further enhance the properties of layers 1105 and 1106, denoted by layer 1107 in FIG. 11. Examples of materials used for this layer include but are not limited to MgO, GdO, AlO, MgAlO, and MgTiO. As can readily be appreciated, MTJs in accordance with various embodiments of the invention can be implemented with a variety and different combinations of material. Furthermore, although FIG. 11 illustrates a specific configuration of an MTJ, MTJs can be constructed to have a variety of different layer configurations.

### MTJs Incorporating Free Layer Insertions

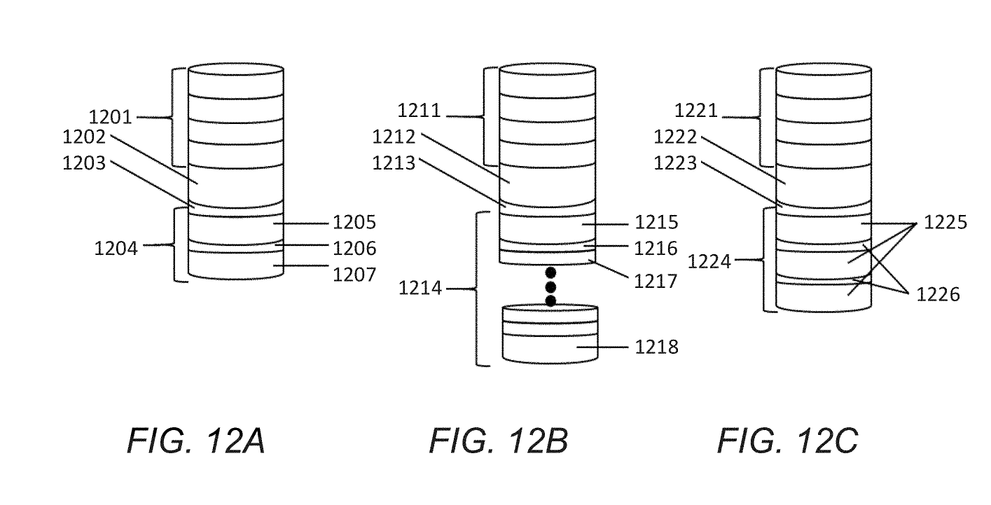

Many embodiments of the invention are directed to MTJ structures with materials inserted into the free layer. Schematic illustrations of some such embodiments are provided in FIGS. 12A to 12C. As shown, in these embodiments layers 1201, 1211, and 1221 are pinning layers composed of multiple repetitions of materials such as but not limited to Co/Pt, Co/Pd, Co/Ni, etc. Layers 1202, 1212, and 1222 are reference layers composed of materials such as but not limited to CoFeB, CoFe, CoFeAl, CoB, FeB, etc., and layers 1203, 1213, and 1223 are tunneling barrier layers composed of materials such as but not limited to MgO, AlO, etc. Finally, the multilayers denoted as layers 1204, 1214, and 1224 are free layers.

In various embodiments, as shown in FIG. 12A, the free layer 1204 can be composed of at least three layers 1205, 1206, and 1207. In such embodiments, layers 1205 and 1207 can include materials found in the standard free layer (e.g., CoFeB, CoFe, CoFeAl, CoB, FeB, etc.), and layer 1206 can include materials such as Ir, W, Mo, Ta, Pt, Hf. Re, Os, Ru, MgO, Mg, Cr, V, Mn, Bi, Cu, etc.

In various other embodiments, as shown in FIG. 12B, the free layer 1214 can be composed of multiple insertion layers. In such embodiments, layers 1215 and 1218 can include materials found in the standard free layer (e.g., CoFeB, CoFe, CoFeAl, CoB, FeB), with the remaining layers (1216 and 1217 included) being any combination of such materials such as, but not limited to, Ir, W, Mo, Ta, Pt, Hf, Re, Os, Ru, MgO, Mg, Cr, V, Mn, Bi, Cu, etc., with combinations such as but not limited to Ir/Mo, Ir/W, Ir/Cr, Cr/Ir, Ta/Mo, Ta/W, Ta/MgO, Cr/Mo, Cr/W, and MgO/Cr, MgO/Ir, Mo/Ir/Mo, W/Ir/W, Mo/Ta/Mo, W/Ta/W, etc.

In still other embodiments, as shown in FIG. 12C, the free layer 1224 can be composed of insertion repetitions (layers 1225, 1226). In such embodiments, layer 1225 can include materials found in the standard free layer (e.g., CoFeB, CoFe, CoFeAl, CoB, FeB, etc.). Layer 1226 can be either a single material, or multiple layers of materials, consisting of any combination of materials such as but not limited to Ir, W, Mo, Ta, Pt, Hf, Re, Os, Ru, MgO, Mg, Cr, V, Mn, Bi, Cu, etc., with combinations such as for example, Ir/Mo, Ir/W, Ir/Cr, Cr/Ir, Ta/Mo, Ta/W, Ta/MgO, Cr/Mo, Cr/W, and MgO/Cr, MgO/Ir, Mo/Ir/Mo, W/Ir/W, Mo/Ta/Mo, W/Ta/W, etc.

Furthermore, any and all combinations of the aforementioned free layer insertions can be utilized to further enhance the VCMA effect within the free layer.

### Tunneling Barrier Interface Insertion/Dusting

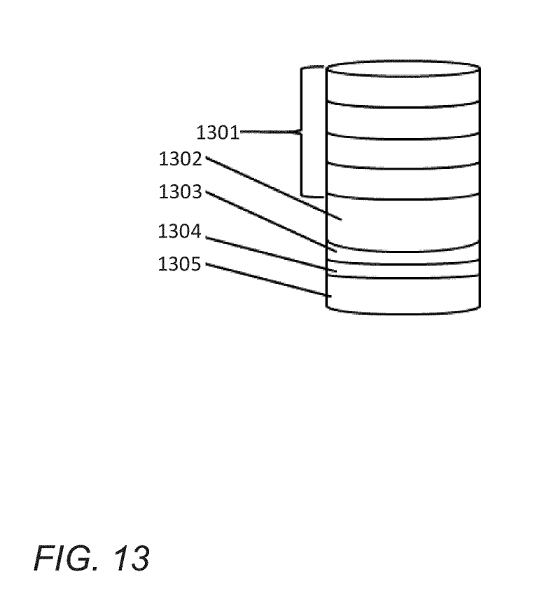

Many embodiments are directed to MTJ structures with material(s) inserted at the interface between the tunneling barrier and free layer. Schematic illustrations of such structures are conceptually illustrated in FIG. 13. In the illustrative embodiment, layer 1301 is a pinning layer, which is typically composed of multiple repetitions of Co/Pt, Co/Pd, Co/Ni, etc. Layer 1302 is the reference layer, which is typically composed of CoFeB, CoFe, CoFeAl, CoB, FeB, etc. Layer 1303 is the tunneling barrier, which is typically composed of MgO, AlO, etc. In such embodiments, layer 1304 can be configured as the insertion point (between the tunneling barrier 1303 and free layer 1305) for one or multiple materials, such as but not limited to Ir, W, Mo, Ta, Pt, Hf, Re, Os, Ru, MgO, Mg, Cr, V, Mn, Bi, Cu, Gd, GdO, AlO, Al, etc.

### Tunneling Barrier Seed

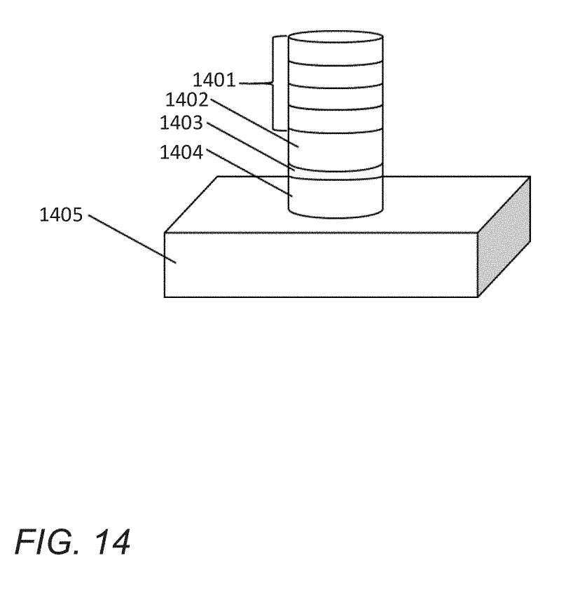

Many embodiments are directed to MTJ structures with seed layers. Schematic illustrations of some such embodiments are provided in FIG. 14. Similar to the structures as described above, the structure shown in FIG. 14 includes a pinning layer 1401, a reference layer 1402, a tunneling barrier 1403, and a free layer 1404. In the illustrative embodiment, the structure further includes a seed layer 1405 that is typically composed of materials such as but not limited to Ir, W, Mo, Ta, Pt, Hf, Re, Os, Ru, MgO, Mg, Cr, V, Mn, Bi, Cu, etc. In such embodiments, the seed layer can also include materials mirroring the tunneling the barrier, such as but not limited to MgO, GdO, AlO, MgAlO, and MgTiO, etc.

### Oxidation Control of the Tunnel Barrier

Although the above embodiments have described specific MTJ structures including insertions of layers, it will be understood other embodiments can include methods of controlling the oxidation of the tunnel barrier during deposition. In many such embodiments, during the deposition of a MTJ, the oxidation of the tunnel barrier, denoted by layer 1403 in FIG. 14, can be controlled by altering the flow of oxygen. Typical materials used during such deposition can include but are not limited to MgO, AlO, Mg, Al, MgAlO, MgAl, MgTi, MgTiO, Gd, GdO, etc. By controlling the flow of oxygen, the concentration of oxygen within the tunnel barrier materials can be increased above that of the deposited material.

### DOCTRINE OF EQUIVALENTS

While the above description contains many specific embodiments of the invention, these should not be construed as limitations on the scope of the invention, but rather as an example of one embodiment thereof. It is therefore to be understood that the present invention may be practiced in ways other than specifically described, without departing from the scope and spirit of the present invention. Thus, embodiments of the present invention should be considered in all respects as illustrative and not restrictive. Accordingly, the scope of the invention should be determined not by the embodiments illustrated, but by the appended claims and their equivalents.

What is claimed is:

1. A magnetic heterostructure comprising:
a stack comprising a plurality of magnetic and insulating layers; and
at least one seed/cap layer disposed adjacent to the stack, wherein the at least one seed/cap layer comprises a material selected from the group consisting of Ir, W, Mo, Ta, Pt, Hf, Re, Os, Ru, MgO, GdO, AlO, MgAlO, Mg, Cr, V, Mn, Bi, and Cu, and combinations thereof.

2. The magnetic heterostructure of claim 1, wherein the at least one seed/cap layer comprises a material selected from the group consisting of Ir/Mo, Ir/W, Ir/Cr, Cr/Ir, Ta/Mo, Ta/W, Ta/MgO, Cr/Mo, Cr/W, MgO/Cr, MgO/Ir, Mo/Ir/Mo, W/Ir/W, Mo/Ta/Mo, and W/Ta/W.

3. The magnetic heterostructure of claim 1, further comprising an additional layer adjacent the seed/cap layer, wherein the additional layer comprises a material selected from the group consisting of MgO, GdO, AlO, MgAlO, and MgTiO.

4. The magnetic heterostructure of claim 3, wherein the additional layer comprises a hybrid material.

5. A magnetic tunnel junction comprising:
a stack comprising a pinning layer, a reference layer, a tunneling layer, and a free layer; and wherein the free layer comprises a plurality of layers, wherein at least one of the plurality of layers comprises a material selected from the group consisting of Ir, W, Mo, Ta, Pt, Hf. Re, Os, Ru, MgO, Mg, Cr, V, Mn, Bi, Cu, and combinations thereof.

6. The magnetic tunnel junction of claim 5, wherein at least two layers of the plurality of layers comprises a material selected from the group consisting of Ir, W, Mo, Ta, Pt, Hf, Re, Os, Ru, MgO, Mg, Cr, V, Mn, Bi, Cu, and combinations thereof.

7. The magnetic tunnel junction of claim 6, wherein the at least two layers are separated by at least one ferromagnetic layer.

8. The magnetic tunnel junction of claim 7, wherein the at least one ferromagnetic layer comprises a material selected from the group consisting of CoFeB, CoFe, CoFeAl, CoB, and FeB.

9. The magnetic tunnel junction of claim 5, wherein the flow of oxygen is controlled during deposition of the tunnel layer.

10. A magnetic tunnel junction comprising:
a stack comprising a pinning layer, a reference layer, a tunneling layer, and a free layer; and at least one insertion layer disposed between the tunneling layer and the free layer, wherein the insertion layer comprises a material selected from the group consisting of Ir, W, Mo, Ta, Pt, Hf, Re, Os, Ru, MgO, Mg, Cr, V, Mn, Gd, GdO, AlO, Al, and Bi.

11. The magnetic tunnel junction of claim 10, wherein the insertion layer comprises two separate adjacent layers, wherein each of the two separate adjacent layers comprises a material selected from the group consisting of Ir, W, Mo, Ta, Pt, Hf, Re, Os, Ru, MgO, Mg, Cr, V, Mn, Gd, GdO, AlO, Al, and Bi.

12. The magnetic tunnel junction of claim 10, wherein the flow of oxygen is controlled during deposition of the tunnel layer.

13. A magnetic tunnel junction comprising:
a stack comprising at least a pinning layer a reference layer, a tunneling layer, and
a free layer; and
at least one insertion layer disposed between the tunneling layer and the free layer, wherein the at least one insertion layer comprises a material selected from the group consisting of Ir, W, Mo, Ta, Pt, Hf. Re, Os, Ru, MgO, Mg, Cr, V, Mn, Bi, and Cu, Gd, GdO, AlO, Al, and combinations thereof.

14. The magnetic tunnel junction of claim 13, further comprising a seed layer, wherein the seed layer comprises a material selected from the group consisting of Ir, W, Mo, Ta, Pt, Hf, Re, Os, Ru, MgO, Mg, Cr, V, Mn, Bi, Cu, MgO, GdO, AlO, MgAlO, MgTiO, and combinations thereof.

15. The magnetic tunnel junction of 13, wherein the flow of oxygen is controlled during deposition of the tunnel layer.
